(19) United States
(12) Patent Application Publication
(10) Pub. No.: US 2013/0307117 A1
(43) Pub. Date: Nov. 21, 2013

(54) Structure and Method for Inductors Integrated into Semiconductor Device Packages

(71) Applicant: Sreenivasan KODURI, Allen, TX (US)

(72) Inventor: Sreenivasan KODURI, Allen, TX (US)

(73) Assignee: TEXAS INSTRUMENTS INCORPORATED, Dallas, TX (US)

(21) Appl. No.: 13/475,439

(22) Filed: May 18, 2012

(51) Int. Cl. H01L 29/86; H01L 21/02; H01L 21/56; H01F 5/00

(52) U.S. Cl. 257/531; 336/200; 438/381; 438/127; 257/E29.325; 257/E21.022; 257/E21.502

(57) ABSTRACT

A thin-contour semiconductor device with a solenoid and iron core integrated into the device package. The solenoid windings are constructed by a stripe-shaped layer portion, deposited on the chip surface, and an arced wire portion welded to the layer portion by low-cost standard wire bonding technique. The stripes are arrayed parallel to each other, spaced apart respective insulating gaps. The arced wires span from one stripe to the adjacent next stripe by bridging the gap and keeping the clock direction constant. The arced solenoid windings are then integrated into the encapsulating device package. The ferromagnetic core may be shaped as a ring to allow the formation of a strong and nearly homogeneous magnetic field inside the solenoid, providing reliable energy storage for power supply circuits.

### FIELD

Embodiments of the invention relate in general to the field of semiconductor devices and processes, and more specifically to the structure and fabrication method of semiconductor integrated circuit devices, which integrate the inductors of the circuits into the package of the devices.

### DESCRIPTION OF RELATED ART

Inductors are essential elements for RF design. Based on planar spiral inductor models first published in 1996 and on the high level of semiconductor technology and device production, planar spiral inductors and planar solenoidal inductors of a wide variety of thin-film single-layered and double-layered designs are available in electronic products with integrated circuits (IC) for RF application. The inductors of these semiconductor products realize the needed inductances by silicon on-chip thin-film spiral and solenoidal designs incorporated into the two-dimensional layout of ICs. Since the inductance of an inductor is proportional to the magnetic permeability of the material inside the inductor, the relatively small inductances sufficient for the RF devices can be generated while accepting the low permeabilities of air and insulators.

On the other hand, when products require higher inductances and have to employ ferromagnetic materials containing iron because of the about 1000 times higher magnetic permeability of iron, the needed inductors are created by piece-part components assembled on the IC surface, thus towering into the third dimension over the two-dimensional IC. As an example, electronic products such as laptop computers, hand-held telephones and notebooks require different electrical supply voltages in order to operate the various component parts (such as integrated circuits, monitors, displays, speakers, clocks, etc.) within their most effective regimes. In addition, these voltages have to be available at reliably constant levels in order to guarantee uniform and trouble-free operation of the component parts. The plurality of voltages and the constant voltage levels are provided and controlled by so-called DC-DC power supply devices.

A typical DC-DC power supply circuit, as it is used in many laptop computers with liquid crystal displays, may have a battery whose voltage is subject to some variation due to usage and ambient temperature. To stabilize the battery voltage output and modulate it for the different voltages required by the various computer components, the circuit includes two lateral field effect transistors (FETs), which are coupled in series with a common terminal; the drain of the first transistor receives the input voltage from a battery, the source of the second transistor is connected to ground potential. The gates of the transistors are operated and coordinated by a driver circuit, which in turn is regulated by a control circuit. The common terminal is connected to an inductor, which stores the energy of the device in the magnetic field inside its solenoid; the magnetic field, in turn, needs high permeability in the inductor to reach high field values. The inductor provides the desired output voltage at the required constant level.

As an electronic device part in a laptop computer, notebook, etc., today's exemplary DC-DC-power supply is built on a rectangular printed circuit board of approximately 16 by 19 mm side length. The plastic packaged ICs, transistors, etc. are physically small (in the millimeter regime) and are soldered on the board, giving the board a slim, essentially two-dimensional appearance (of less than 3 mm height). However, sticking out into the third dimension is the separate piece part of the inductor with an area requirement of 5 by 5 mm and an additional height of 5 mm for the solenoid filled with an iron core (total height about 8 mm).

### SUMMARY

Applicant recognized that the market trends in electronic products such as laptop computers, notebooks, smartphones and the like demand products, which are thin, light weight, and low cost. As a consequence, he saw that product parts such as DC-DC power supplies with bulky and relatively costly three-dimensional inductors for achieving high magnetic field energy levels need to be modified to achieve slim contours, lower weight, and lower cost.

Applicant found that for creating a volume inside a solenoid sufficient to place an iron core for achieving high magnetic field energy levels, the conventionally employed circular shape of the windings is not essential. Instead, applicant discovered that the cross section of a solenoid winding can be split into a linear portion incorporated into the flat chip surface with the two-dimensional IC, and a three-dimensionally curved portion incorporated into the package encapsulating the chip.

Applicant solved the problem of fabricating a solenoid combining an iron core with the thin contour of a semiconductor device, when he detected that the iron core can be integrated into the standard device backend assembly flow, and that the three-dimensionally curved portions of the solenoid windings can be fabricated by the low cost process of arching wires as in the standard wire bonding technology. The arched wires of the solenoid windings are then integrated into the device package needed anyway to protect the wire bond connections of the chip.

In the process flow of the invention, each solenoid winding is constructed of a layer portion and a wire portion. The layer portion is realized as an elongated trace of stripe-shaped metal thin film; in preferred embodiments, the stripe lays flat on the insulation over the chip surface. The layer may be created by depositing metal using techniques such as plating, silk screening, sputtering, evaporation, and chemical vapor deposition, followed by a stripe-patterning step as needed. Each stripe has a first end and a second end; consecutive stripes are preferably arrayed parallel to each other, spaced apart by a respective insulating gap. After covering the center portions of the stripes with an insulating film, an iron sheet is deposited by standard semiconductor fabrication steps on the insulating film extending across the parallel stripes and gaps. The wire portion is realized as a wire or ribbon arch spanning from one stripe to the next.

The wires are welded to the stripes and connect the stripes so that the first wire, welded to the first end of the first stripe, spans an arch over the stripe center portion and the adjoining gap to the second end of the adjacent second stripe; the second wire, attached to the first end of the second stripe, spans an arch over the stripe center portion and the adjoining gap to the second end of the adjacent third stripe; and so on to the last stripe. Consecutive wires are preferably arrayed parallel to each other. Thus, a solenoid with orderly windings for a constant clock direction emerges. The welding can be achieved by low-cost techniques such as ball bonding, stitch bonding, and pressure bonding. The solenoid is connected to external parts by spanning a wire from the second end of the first stripe to a package contact pad, and another wire from the first end of the last stripe to another package contact pad, creating an inductor. For protection, all wires may be embedded in the packaging compound encapsulating the chip surface employed for package robustness.

Some embodiments may have two elongated solenoids arranged in parallel and serially connected so that the electrical current continues in the same clock direction in both solenoids. With this arrangement, the iron core of the first solenoid may continue, after a U-turn, as the core of the second solenoid, enhancing the inductor performance. In other embodiments, the parallel solenoid arrangement has an iron core closed as a ring by adding another U-turn to the iron portions through the individual solenoids, resulting in a specially powerful inductor and energy storage device.

It is a technical advantage of the invention that the fabrication of the inductors need only low cost common package manufacturing processes and equipment. It is another technical advantage that the inductors of the invention can be integrated into the packages as part of the slim device dimensions.

As an example, a packaged 48-pin TSSOP embodiment has its inductor with 15 windings of 150 μm arch height and an iron plate of 2.75 mm by 0.5 mm by 0.05 mm integrated into its slim package of outline 12.5 mm by 6.1 mm by 1.2 mm. The height of only 1.2 mm represents a reduction of more than 80% compared to the conventional height of about 8 mm.

### BRIEF DESCRIPTION OF THE DRAWINGS

FIG. 1 is a schematic perspective view of an embodiment of the invention illustrating a semiconductor device package integrated with a solenoid having an iron sheet inside the windings formed partially by arched wires and partially by flat metal stripes.

FIG. 2 shows a schematic top view of the embodiment in FIG. 1.

FIGS. 3 to 5 are schematic top views of the dielectric-covered semiconductor chip illustrating certain steps in the process flow of fabricating a solenoid with a core of ferromagnetic material according to the invention.

FIG. 3 is a schematic top view depicting the process step of forming a plurality of parallel metal stripes on the dielectric layer over an IC, the center portions of the stripes being covered by an insulating film.

FIG. 4 shows a schematic top view depicting the process step of adhesively attaching a sheet of ferromagnetic material over the insulator-covered center portions of the plurality of metal stripes.

FIG. 5 is a schematic top view depicting the process step of connecting the metal stripes with arched wires by bridging the iron core and the stripe gaps to the adjacent stripe in the sequence prescribed by the invention to create a solenoid with constant direction of the windings.

FIG. 6 shows a schematic top view of the ferromagnetic core according to another embodiment of the invention.

FIG. 7 illustrates a schematic top view of the ferromagnetic core according to yet another embodiment of the invention.

FIG. 8 is a schematic circuit diagram of a DC-DC power supply including two field effect transistors coupled to an inductor structured according to the invention.

### DETAILED DESCRIPTION OF THE PREFERRED EMBODIMENTS

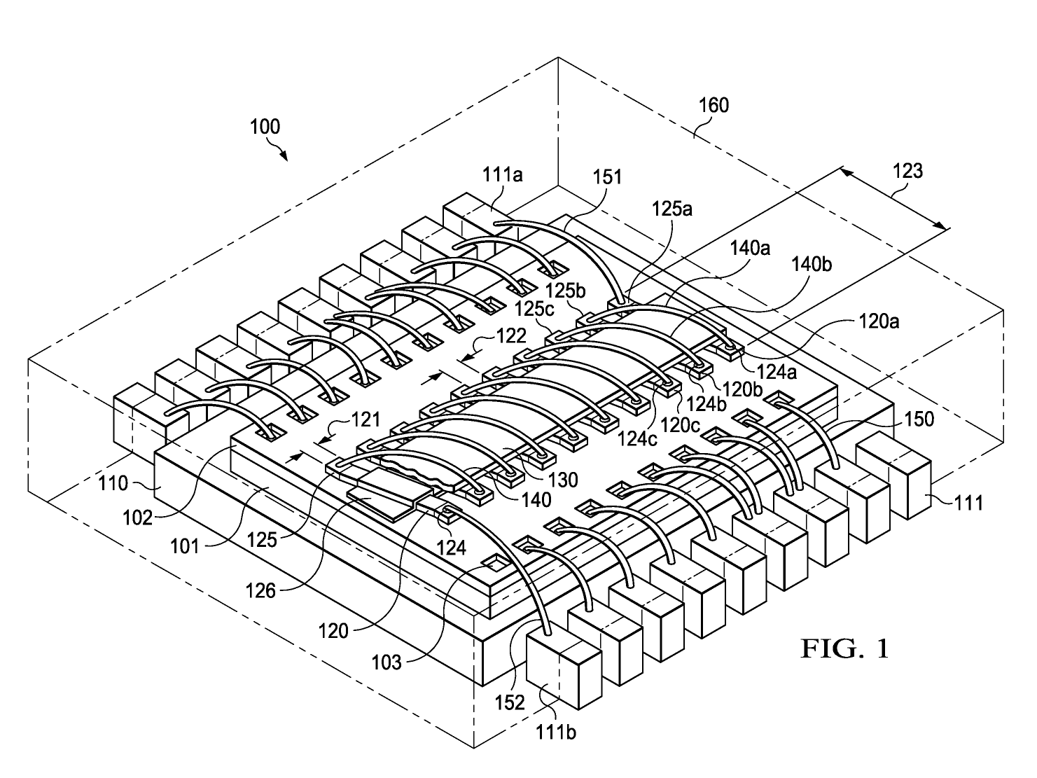

The exemplary embodiment of the invention illustrated in FIG. 1 and generally designated 100 shows a solenoid integrated into the package of a semiconductor device according to the invention. A semiconductor chip 101, for instance made of silicon, has a dielectric layer 102, for instance silicon oxynitride, over its integrated circuitry. The terminals 103 of the circuitry are not covered by the dielectric layer so that electrical contacts can be affixed to the circuitry; in the exemplary device 100, the terminals are realized as bond pads. Preferred bond pad metals include aluminum, or a stack of nickel and gold. Chip 101 is attached to a substrate 110. In the example of FIG. 1, substrate 110 is shown as the chip pad of a metallic leadframe, but in other devices substrate 110 may be a laminated multi-metal layer composite or another suitable insulating carrier. The chip attachment layer, for instance an adhesive polymer material, is not shown in FIG. 1.

Laying flat on the dielectric layer 102, and adhering to it, is a plurality of deposited metal stripes 120. The stripes are arrayed parallel to each other. Preferably, the stripes have the same length 123 and the same width 121. Each stripe has a first end 124 and a second end 125; preferably, the first ends 124 of the stripe plurality are linearly arrayed, and the second ends 125 are linearly arrayed. The metal of the stripes is exposed at each first and second end. The center portion of the stripes, however, is covered by an insulating film 126 laying over the stripes, which is patterned to leave the first (124) and second (125) ends of the strips un-covered. Film 126 may be made of polyimide, silicon dioxide, or any other suitable insulator. Adjacent stripes are spaced from each other by gaps 122, which are controlled by dielectric material (dielectric layer 102 and insulating film 126). As a consequence, adjacent stripes are electrically isolated from each other. Gaps 122 have preferably the same width for all gaps. The stripes are made of a first metal selected for high electrical conductivity. Preferably, the first metal is copper and the stripe a layer of copper in the thickness range from about 10 to 75 μm, covered by a bondable metal film (such as gold or silver); alternatively, the first metal may be silver or a metal alloy.

The metal of the stripes 120 is deposited on the dielectric layer 102 as a film or layer. The deposition methods include plating, sputtering, evaporating, silk screening, and chemical vapor deposition. If the layer is deposited as a large-area layer, follow-up photoresist and etching steps are required for patterning the layer into the plurality of stripes 120.

FIG. 1 further shows a body of a ferromagnetic material, such as iron for example, depicted as sheet 130, laying on the insulating film 126; sheet 130 extends substantially across the plurality of stripes. The iron sheet has preferably a thickness in the range from about 25 to 75 μm (about 50 μm for exemplary 150 μm wire arch height). The ferromagnetic material of sheet 130 is preferably a pre-fabricated piece part selected for high ferromagnetic permeability; generally, the ferromagnetic permeability is a dimensionless number on the order of 1000 and dependent on the magnetic history of the material. Alternatively, ferromagnetic material may be deposited as a layer, which is then patterned to fit the geometry of the insulating film 126 over the central portions of the stripes.

As shown in FIG. 1, electrically conductive wires 140 connect the first end of each stripe to the second end of the consecutive adjacent stripe by spanning an arc over the stripe center portion and the adjoining gap. Wires 140 are made of a second metal, which is preferably copper and alternatively gold. The preferred wires have a circular cross section with a diameter between about 17 and 30 μm, but thicker or thinner wires may be used. Alternatively, ribbons may be used. The wires are welded to the stripes; the welding methods include ball bonding, wedge bonding, and pressure bonding. After interconnecting the plurality or stripes, the wires form a set of approximately parallel arches, resembling a portion of a round coil. While the preferred method of spanning the wire arches uses the highly controllable and low cost wire ball bonding technique of the semiconductor assembly technology, an alternative method employs a pre-fabricated half coil, which may be placed on the ends of the stripes.

As an example in FIG. 1, let the first stripe be designated 120a, its first end 124a and its second end 125a; the second stripe be designated 120b, its first end 124b and its second end 125b; the third stripe be designated 120c, its first end 124c and its second end 125c; and so forth. As illustrated in FIG. 1, the first wire 140a is attached to the first end 124a of the first stripe 120a and spans an arc over the stripe center portion, the iron sheet, and the adjoining gap to the second end 125b of the adjacent second stripe 120b. The second wire 140b is attached to the first end 124b of the second stripe 120b and spans an arc over the stripe center portion, the iron sheet, and the adjoining gap to the second end 125c of the adjacent third stripe 120c. This sequence routine continues to the last stripe, creating the substantially rounded portion of the orderly windings of a coil or solenoid. The other portion of the solenoid is formed by the layer stripes, resulting in a solenoid for an electric current in continuous clock direction. The cross section of the solenoid windings is split into the portion of the stripes deposited on the two-dimensional chip surface, and the three-dimensionally arced portion of the wire spans; as mentioned, the arced portions are preferably incorporated into the package encapsulating the chip surface.

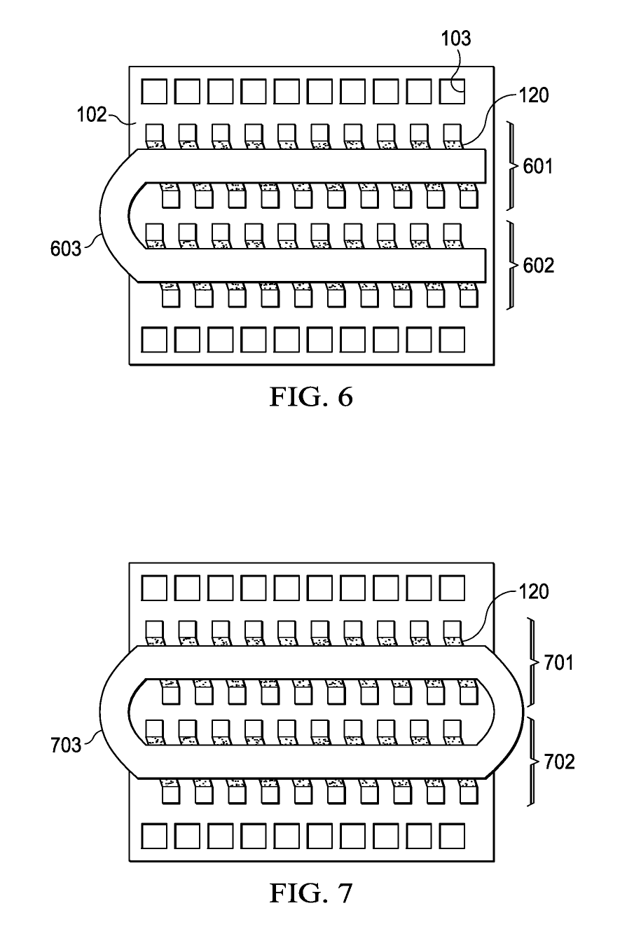

For a very elongated solenoid made of a number of windings, the energy of the magnetic field inside the solenoid is proportional to the inductance of the solenoid and the square of the current through the windings. The inductance, in turn, is proportional to the square of the number of windings, to the cross section of the solenoid, and to the permeability inside the solenoid, and inverse proportional to the length of the solenoid. The dominant factors determining a high energy of the magnetic field inside a solenoid is the high permeability achievable by a ferromagnetic material core, the number of windings, and the amount of current through the windings. While the quoted dependencies are qualitatively valid for short linear solenoids, they are quantitatively valid for circular solenoids; consequently, circular solenoids with iron cores (see FIGS. 6 and 7) provide great magnetic field energies and energy concentrations.

Ferromagnetic material may also be called ferroelectric material.

Ferroelectricity has also been shown to exist in soft biological tissues such as fat. For example, collagen's building block—the amino acid glycine—is ferroelectric when its molecules are arranged in a crystalline lattice. Proteins such as microtubules have been reported to be ferroelectric. Therefore, the term ferromagnetic material in this disclosure may also include biological material which exhibit ferroelectric properties.

As FIG. 1 shows, the exemplary device 100 may employ the low-cost wire ball bonding technique to connect the chip terminals 103 to the contact pads 111 of substrate 110 by wire spans 150. Since the substrate in FIG. 1 is realized by a leadframe with chip attach pad 110, the contact pads 111 are provided by the leads of the leadframe. In addition, FIG. 1 depicts a wire 151 connecting the second end 125a of the first stripe 120a to a contact pad of the substrate (in FIG. 1 specifically a lead of the leadframe), and another wire 152 connecting the first end of the last stripe of the plurality to another contact pad of the substrate. The connection of the solenoid to an external power supply is thus accomplished.

Exemplary device 100 exhibits a package 160, preferably formed by a polymeric encapsulation compound, such as an epoxy-based molding compound, embedding all bonding wires. Device package 160 has the slim contours of a standard semiconductor device, such as the length, width, and height of a Quad Flat No-Lead (QFN) or Small Outline No-Lead (SON) device. Since the embedding in the device encapsulation also includes the solenoid wires 140, the solenoid of the invention is fully integrated into the device package and its slim contours; since it includes a ferromagnetic core, it achieves high magnetic field energies. The solenoid thus no longer needs the bulky and costly three-dimensional shape of the inductors in customary DC-DC power supplies.

As an example, a packaged 48-pin TSSOP embodiment has its inductor with 15 windings of 150 μm arch height and an iron plate of 2.75 mm by 0.5 mm and 50 μm height integrated into its slim package of outline 12.5 mm by 6.1 mm by 1.2 mm. The height of only 1.2 mm represents a reduction of more than 80% compared to the conventional height of about 8 mm (of which less than 3 mm are for the body and about 5 mm for the discrete solenoid component).

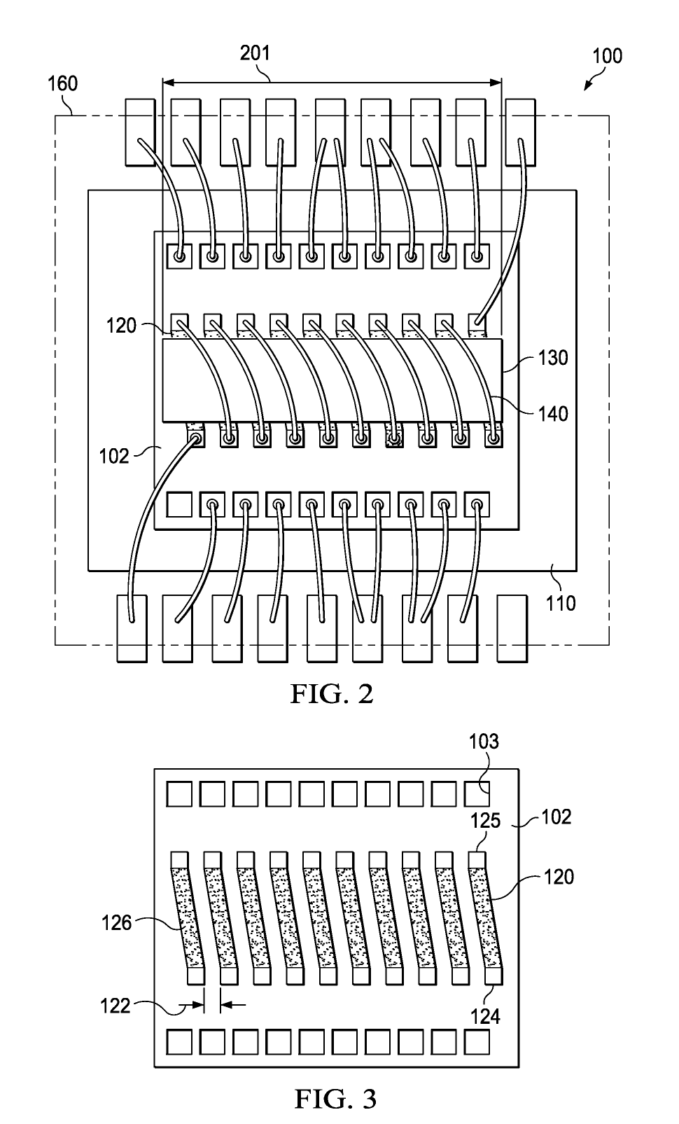

The top view of the exemplary device 100 in FIG. 2 with a transparent encapsulation compound 160 of the package emphasizes the integration of the solenoid into the device package. The view of FIG. 2 depicts the dielectric layer 102 of the chip; the chip itself is not visible in FIG. 2. The chip is attached onto pad 110 of the substrate (leadframe). A plurality of metal stripes 120 is arrayed on the dielectric layer in a pattern of parallel orientation, the stripes spaced by equal gaps, which display the dielectric layer 102. The stripes provide the flat bottom portions of the solenoid windings. Attached to the stripe ends are the bonding wires 140, which arc from stripe end to adjacent stripe end in the manner described above; the wires provide the arcing top portions of the solenoid windings. As a result, a solenoid of length 201 is formed; the number of solenoid windings is determined by the plurality of stripes, and the cross section of the solenoid is determined by the cross section of the wire arches.

While the insulating film covering the center portions of the stripes is not shown in FIG. 2, its presence is indicated by a stripe surface different in the center portions compared to the stripe ends, which are not covered by the insulating film. Laying across the insulated center portions of stripes 120 is iron sheet 130, which provides the core of the solenoid and determines the high magnetic permeability and thus the high inductance inside the solenoid. As stated, a high inductance supports a high energy of the magnetic field inside the solenoid.

FIGS. 3 to 5 illustrate certain steps of the fabrication process flow for fabricating a solenoid, coupled to an IC, to be integrated into the package of the IC. After the IC has been completed and the chip surface covered with a dielectric layer 102 (for instance, by forming moisture-impermeable layers of silicon dioxide and silicon nitride or silicon carbide), while leaving the circuit terminals and bond pads 103 un-covered, the chip is attached to a substrate with contact pads. The substrate may be the chip pad of a leadframe or any other suitable carrier and the contact pads may be the leads of the leadframe. FIG. 3 shows the deposition and formation of flat parallel metal stripes 120 on the surface of the dielectric layer 102. In the preferred method of stripe formation, a photolithographic technology is used to create a plurality of windows in a photoresist layer; the windows represent in number, shape and orientation of the future stripes. A copper layer of about 25 to 75 μm height is then deposited, preferably by plating, in the windows; a thin layer of silver may be deposited over the copper to enhance bondability. Alternatively, a silver layer of comparable thickness may be deposited. The photoresist is removed, and the stripes 120 and the dielectric chip surface in the gaps 122 are exposed. Each stripe has a first end 124 and a second end 125.

The stripes serve as the two-dimensional portions of the forth-coming solenoid windings. Since the magnetic performance of the solenoid is proportional to the square of the windings number, it is advantageous to pack as many stripes as possible into the given length of the dielectric-covered chip surface, whereby the aspect ratio between stripe height and gap width needs to be taken into account. Consequently, the stripes are preferably positioned in an orderly sequence, oriented in parallel and with equal gaps between adjacent stripes, and have the same length with their endpoints arrayed linearly. Since the magnetic performance of the solenoid is proportional the square of the electric current through the stripe, it is advantageous to minimize the resistance per square of the stripe and to make the electrical resistance of the stripe equal to the resistance of the equally long wire-to-be-employed.

In the next process step, also indicated in FIG. 3, the center portions 126 of the stripes 120 are covered with an insulating film, such as polyimide, preferably having an adhesive outside. In FIG. 3, the film is assumed to be transparent and if thus not shown; however, the film's consequence, namely to provide an insulating surface to the center portions of the stripes, is indicated by the shading of the stripe center portions 126. The first ends 124 and the second ends 125 remain un-covered by the film so that the stripe metal can be contacted and receive metallic bonds.

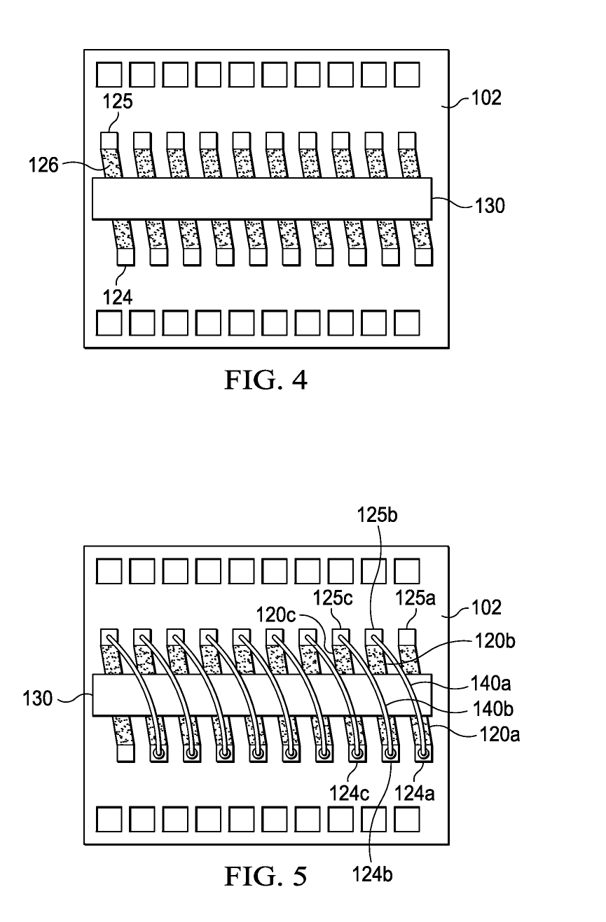

FIG. 4 illustrates the optional next process step. An iron sheet 130 is deposited on the insulating adhesive film over the stripes so that the iron sheet extends substantially across the whole plurality of stripes. The width of the iron sheet as the core of the future solenoid is such it covers as much of the stripe length as possible but keeps some distance to the first and second stripe ends (124, 125 respectively) in order to allow wire bonds to be attached to the first and second ends without risk of touching the iron sheet. The preferred thickness range of the iron sheet is from about 25 to 75 μm. The iron sheet has preferably a cuboid shape, but it may alternatively have a trapezoidal or hemispherical cross section. The iron sheet 130 is low cost. While it is preferred to use a pre-fabricated iron sheet, another low-cost alternative is the process of depositing an iron layer of sufficient thickness and then patterning the layer into an outline to fit over the stripes and into the arched wires to be formed next.

In the next process step, shown in FIG. 5, the metal stripes are interconnected by arched wires to create a solenoid. The preferred method is a conventional computer-controlled, low-cost wire ball bonding technique using an automated wire bonder. The software of the bonder is set so that the stripes are connected with the adjacent ones to allow an electrical current to run through the wires and stripes in a constant clock direction. In the example outlined above and illustrated in FIG. 5, the first stripe may be designated 120a, its first end 124a and its second end 125a; the second stripe be designated 120b, its first end 124b and its second end 125b; the third stripe be designated 120c, its first end 124c and its second end 125c; and so forth. As illustrated in FIG. 5, the first wire 140a is attached to the first end 124a of the first stripe 120a and spans an arc over the stripe center portion, the iron sheet, and the adjoining stripe gap to the second end 125b of the adjacent second stripe 120b. The second wire 140b is attached to the first end 124b of the second stripe 120b and spans an arc over the stripe center portion, the iron sheet, and the adjoining stripe gap to the second end 125c of the adjacent third stripe 120c. This sequence routine continues to the last stripe, creating the arcing portion of the orderly windings of a coil or solenoid.

The other half of the solenoid is formed by the flat stripes, resulting in a solenoid for an electric current in continuous clock direction. The cross section of the solenoid windings is split into the stripe-portion on the two-dimensional chip surface, and the three-dimensionally curved portion of the wire spans, which preferably is incorporated into the package encapsulating the chip. Inside the solenoid is the iron core 130.

As an alternative process step, the sequence of wire arches is pre-fabricated as a half coil and placed on the stripe ends in one piece. Inside the half coil is the iron core of the solenoid.

In the next process step, the solenoid is connected to an external power supply. The result is shown in FIG. 1: A wire 151 is spanned from the second end 125a of the first stripe 120a to a contact pad 111a of the substrate, and another wire 152 is spanned from the first end of the last stripe to a contact pad 111b of the substrate.

After the step of connecting the chip terminals 103 to the contact pads 111 of the substrate (in FIG. 1 formed as leads 111 of a leadframe), the next step is the packaging of the assembled chip and integrated inductor in an encapsulation compound 160. The bonding wires, chip surface and solenoid windings are thus protected. In QFN and SON devices, the encapsulation compound covers the wire arches, but may leave the bottom of the substrate (chip pad) and of the leads un-covered, keeping the height of the packaged device low.

FIG. 6 illustrates another embodiment of the invention, which has the numerous windings of a solenoid grouped in two sections 601 and 602, coupled together by a bent yet continuous iron core 603 placed over both sections. Since the strength of an inductor is proportional to the square of the number of windings and the permeability inside the solenoid (among other factors mentioned above), the integration of the two solenoid sections and the iron core into the device package offers the IC of the device a specially high inductance and energy concentration in the inductor. For clarity reasons, the device of FIG. 6 is depicted after the process step of depositing the iron sheet, but before the step of interconnecting the metal stripes by wire arches to complete the solenoid windings; consequently, FIG. 6 shows only the parallel metal stripes 120 as the (substantially) flat portions of the solenoid windings.

The embodiment of FIG. 6 still allows the exit of magnetic field lines from the iron core into the ambient, and thus a certain percent of loss of inductance and energy concentration in the inductor. In contrast, FIG. 7 depicts another embodiment of the invention with a closed iron core. For clarity reasons, the embodiment of FIG. 7 is depicted after the process step of depositing the iron sheet, but before the step of interconnecting the metal stripes by wire arches to complete the solenoid windings. The numerous parallel metal stripes 120 as the (substantially) flat portions of the solenoid windings are grouped in two sections 701 and 702, coupled together by a continuous, ring-like looped iron core 703 placed over both sections. The iron ring creates a nearly homogeneous magnetic field inside the solenoid, which is strong due to the high permeability of the iron material. The high inductance enables a high energy concentration, even for only modest electrical currents through the solenoid.

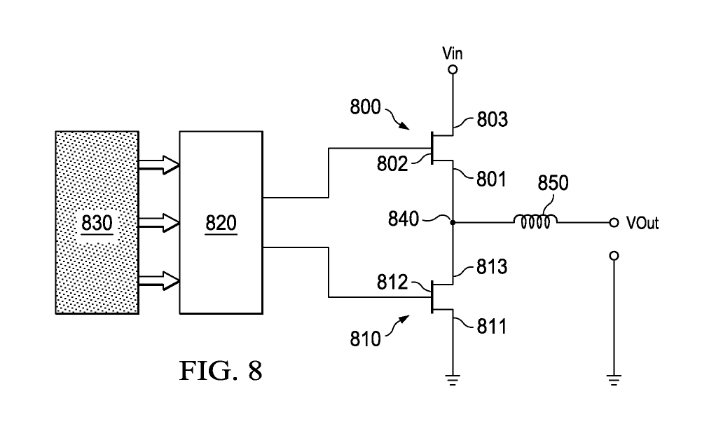

The high inductances of the embodiments of FIGS. 6 and 7 are favorable devices for storing energy in applications such as the frequently employed DC-DC power supply circuit depicted in FIG. 8. In the example of FIG. 8, a first field effect transistor 800, sometimes referred to as the “high” transistor, has its drain 803 connected to the input voltage Vᵢₙ and its source 801 coupled to the drain 813 of the second field effect transistor 810, sometimes referred to as the “low” transistor. The source 811 of transistor 810 is at ground potential. The gate 802 of transistor 800 and the gate 812 transistor 810 are operated by the gate driver 820, which in turn is regulated by controller 830. The common connection between source 801 and drain 813 operates as the switch, designated 840. This switch 840 is coupled to the inductor 850 serving as the energy storage of the power supply circuit, which has to be large enough to reliably function for maintaining a constant output voltage Vₒᵤₜ.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to devices with any type of substrate including to leadframe-based devices. Other substrates include multi-layer insulating polymeric or ceramic substrates, or other boards used in semiconductor devices. As another example, the invention not only applies to QFN/SON type devices, but to any type of semiconductor devices.

As another example, the method can be extended to incorporate any volume into the package of semiconductor devices when the volume can be broken up into a substantially two-dimensional portion, which can be integrated into the chip-based elements, and a substantially three-dimensional portion, which can be integrated into the package-based elements. The invention is thus applicable to certain MEMS-type devices.

As another example, while the method of easily integrating an iron core into the standard semiconductor assembly flow is preferred for magnetic-based devices, it can applied to other devices in need of other cores or crystals.

It is therefore intended that the appended claims encompass any such modifications or embodiments.

I claim:

1. An inductor comprising:
a carrier having a surface encapsulated in a packaging compound; and
a coil having a plurality of spiral windings, each winding including a stripe-shaped layer deposited on the carrier surface and a wire welded to the stripe-shaped layer, the wire arcing from a first end of each of a plurality of stripes to the second end of a consecutive adjacent stripe, the wires embedded in the packaging compound.

2. The inductor of claim 1 further including a body of ferrous material inside the coil.

3. The inductor of claim 2, wherein the ferrous material includes iron.

4. An apparatus comprising:
a semiconductor chip attached to a substrate having contact pads, the chip surface covered by a dielectric layer, the chip bond pads un-covered by the dielectric layer;
a plurality of parallel flat metal stripes on the dielectric layer, the stripes spaced from each other by gaps exposing the dielectric layer; and
wires connecting the first end of each stripe to the second end of the consecutive adjacent stripe by spanning an arch over the stripe center portion and the adjoining gap.

5. The apparatus of claim 4 further including an insulating film over the stripes, the film covering the center portions of the stripes and leaving the first and second ends of the stripes un-covered.

6. The apparatus of claim 5 further including a sheet of ferrous material on the insulating film, the sheet extending across the plurality of stripes.

7. The apparatus of claim 6, wherein the ferrous material includes iron.

8. The apparatus of claim 7 wherein the height of the iron sheet is between about 25 and 75 μm.

9. The apparatus of claim 8 wherein the wires span arches over the iron sheet.

10. The apparatus of claim 4 further including a wire connecting the second end of the first stripe to a contact pad of the substrate, and another wire connecting the first end of the last stripe of the plurality to another contact pad of the substrate.

11. The apparatus of claim 10 further including a packaging compound encapsulating the wires and the chip.

12. The apparatus of claim 4 wherein the substrate is a leadframe including a chip attach pad and leads.

13. The apparatus of claim 12 further including wires connecting the chip bond pads to respective leads of the leadframe.

14. The apparatus of claim 4 wherein the stripes have equal length from the first end to the second end.

15. The apparatus of claim 4 wherein the parallel stripes are positioned to have the first ends arrayed along a straight line.

16. The apparatus of claim 4 wherein the stripes are made of a first metal.

17. The apparatus of claim 4 wherein the wires are bonding wires made of a second metal.

18. A method for fabricating a semiconductor device comprising:
providing a semiconductor chip attached to a substrate having contact pads, the chip having a dielectric layer covering the chip surface and leaving the chip bond pads un-covered;
depositing a plurality of metal stripes on the dielectric layer so that the stripes are parallel and are spaced from each other by gaps exposing the dielectric layer, each stripe having a first end and a second end; and
connecting the first end of each stripe to the second end of the consecutive adjacent stripe by spanning an arch over the stripe center portion and the adjoining gap.

19. The method of claim 18 further including covering the center portions of the stripes with an insulating film, leaving the first and second ends of the stripes un-covered by the film.

20. The method of claim 19 further including depositing a ferrous material sheet on the insulating film so that the ferrous material sheet extends across the plurality of stripes.

21. The method of claim 20, wherein the ferrous material sheet is an iron sheet.

22. The method of claim 21 further including spanning the wire arches over the iron sheet after connecting.

23. The method of claim 21 further including connecting the second end of the first stripe to a contact pad of the substrate by spanning a wire, and connecting the first end of the last stripe of the plurality to another contact pad of the substrate by spanning another wire.

24. The method of claim 23 further including encapsulating the wires and the chip in a packaging compound.
